(19) United States
(12) Patent Application Publication
(10) Pub. No.: US 2011/0069251 A1
(43) Pub. Date: Mar. 24, 2011

(54) LIQUID CRYSTAL DISPLAY DEVICE, BACKLIGHT MODULE, AND METHOD OF ASSEMBLING A BACKLIGHT MODULE

(75) Inventors: Ming-Chuan Hung, Hong Kong (CN); Chun-Chang Chiu, Hong Kong (CN); Hsu-Cheng Yeh, Hong Kong (CN); Chuan-Fa Lee, Hong Kong (CN); Chih-Kuei Wang, Hong Kong (CN)

(73) Assignee: TOP VICTORY INVESTMENTS LIMITED, Hong Kong (CN)

(21) Appl. No.: 12/887,158

(22) Filed: Sep. 21, 2010

(30) Foreign Application Priority Data
Sep. 22, 2009 (TW) 098131912

(51) Int. Cl. G02F 1/1335; H05K 13/00; F21V 7/22

(52) U.S. Cl. 349/62; 29/592.1; 362/606

(57) ABSTRACT

A backlight module includes a first light source, a back plate unit, a reflector unit, and a light guide plate. The back plate unit includes a first back plate and a second back plate. The first back plate has a first plate body with a first side part structure defining a first receiving space for receiving the first light source, and the second back plate has a second plate body with a second side part structure. The second back plate is connected to the first back plate in a manner that the first and second side part structures are opposite to each other. The reflector unit is disposed on the first and second plate bodies, and has a portion extending into the first receiving space. The light guide plate is disposed on the reflector unit and is disposed between the first and second side part structures.

### CROSS-REFERENCE TO RELATED APPLICATION

This application claims priority of Taiwanese Application No. 098131912, filed on Sep. 22, 2009.

### BACKGROUND OF THE INVENTION

1. Field of the Invention

The present invention relates to a liquid crystal display device, more particularly to a liquid crystal display device that is easy to assemble.

2. Description of the Related At

Referring to FIG. 1, a conventional liquid crystal display device 1 generally includes a backlight module 11, a liquid crystal module 12, a frame 13 and a bezel 14. The liquid crystal module 12 is disposed on the backlight module 11, and the frame 13 is disposed between the backlight module 11 and the liquid crystal module 12. The bezel 14 is sleeved on the liquid crystal module 12 and is connected to the backlight module 11. The backlight module 11 includes a back plate 111, a reflector piece 112, a light guide plate 113, a pair of lamp tubes 114, a pair of lampshades 115, and a plurality of optical films 116. The reflector piece 112, the light guide plate 113 and the optical films 116 are stacked on the back plate 111 in sequence. The lamp tubes 114 and the lampshades 115 are installed adjacent to opposite sides of the light guide plate 113.

Since the backlight module 11 of the liquid crystal display device 1 includes many components, an assembly procedure of the backlight module 11 is complex and time-consuming. Therefore, ways to improve the backlight module 11 to simplify the assembly procedure of the liquid crystal display device 1 are constantly sought by those in the industry.

### SUMMARY OF THE INVENTION

Therefore, an object of the present invention is to provide a liquid crystal display device that can be assembled at lower costs.

The liquid crystal display device of the present invention includes a backlight module, a liquid crystal panel, and a bezel. The backlight module includes aback plate unit, a reflector unit, a light guide plate, and first and second light sources. The back plate unit includes first and second back plates. The first back plate has a first plate body with opposite first and second edge parts, and a first side part structure connected to the first edge part of the first plate body. The first side part structure defines a first receiving space for receiving the first light source, and the first receiving space opens toward the second edge part of the first plate body. The second back plate has a second plate body with opposite first and second edge parts, and a second side part structure connected to the first edge part of the second plate body. The second side part structure defines a second receiving space for receiving the second light source, and the second receiving space opens toward the second edge part of the second plate body. The second back plate is connected to the first back plate in a manner that the first and second side part structures are opposite to each other. The reflector unit is disposed on the first and second plate bodies, and has a portion and another portion extending respectively into the first and second receiving spaces. The light guide plate is disposed on the reflector unit and is disposed between the first and second side part structures.

The bezel includes a surrounding wall disposed to surround the back plate unit, and a press wall connected to a periphery of the surrounding wall. The press wall is disposed to press against the liquid crystal panel for coupling the liquid crystal panel to the backlight module.

Preferably, the second edge part of the second plate body is formed with a recessed surface, and the second edge part of the first plate body overlaps the recessed surface.

Preferably, the second edge part of the first plate body is formed with a plurality of first fastener holes, and the second edge part of the second plate body is formed with a plurality of second fastener holes corresponding to the first fastener holes. The backlight module further includes a plurality of fasteners passing through the first and second fastener holes and fastening together the first and second plate bodies.

Preferably, the portion of the reflector unit that extends into the first receiving space is disposed between the first side part structure and the first light source, and the portion of the reflector unit that extends into the second receiving space is disposed between the second side part structure and the second light source.

Preferably, the first plate body further has opposite third and fourth edge parts that extend between the first and second edge parts of the first plate body. The first back plate further has a pair of first side wall structures, each connected to a respective one of the third and fourth edge parts of the first plate body. Similarly, the second plate body further has opposite third and fourth edge parts that extend between the first and second edge parts of the second plate body. The second back plate further has a pair of second side wall structures, each connected to a respective one of the third and fourth edge parts of the second plate body.

Preferably, the first plate body has one side that confronts the light guide plate and that is formed with a first groove adjacent to the first side part structure. The second plate body has one side that confronts the light guide plate and that is formed with a second groove adjacent to the second side part structure.

Preferably, the first plate body has one side that is opposite to the light guide plate and that is formed with a plurality of first protrusions adjacent to the first side part structure. The second plate body has one side that is opposite to the light guide plate and that is formed with a plurality of second protrusions adjacent to the second side part structure.

Preferably, the first and second light sources are one of lamp tubes and light-emitting diode modules.

Preferably, the backlight module further includes an optical film that is disposed on the light guide plate.

Preferably, the liquid crystal display device further includes a spacer unit that is disposed between the backlight module and the liquid crystal panel, thereby separating the liquid crystal panel from the backlight module.

Another object of the present invention is to provide a backlight module that can be assembled with relative ease.

A method of assembling a backlight module of a liquid crystal display device according to this invention includes the steps of:

A) disposing the reflector unit on the first plate body and the second plate body;

B) disposing the light guide plate on the reflector unit; and

C) interconnecting the first plate body and the second plate body in a manner that the first receiving space and the second receiving space open toward each other, that the portions of the reflector unit respectively extend into the first and second receiving spaces, and that the light guide plate is disposed between the first and second side part structures.

Preferably, when the first and second light sources are lamp tubes, the method of assembling a backlight module further includes, before step A), the step of:

D) disposing each of the first and second light sources at a respective one of the portions of the reflector unit such that each of the first and second light sources is disposed in a respective one of the first and second receiving spaces when the first and second plate bodies are interconnected in step C).

Preferably, when the first and second light sources are light-emitting diode modules, the method of assembling a backlight module further includes, before step A), the step of:

D′) disposing each of the first and second light sources in a respective one of the first and second receiving spaces.

Preferably, step A) is conducted before step B), and step C) is conducted after step B).

Preferably, in step A), the reflector unit is disposed on the first plate body and the second plate body, with the second edge parts of the first and second plate bodies spaced apart from each other.

Preferably, in step C), the second edge parts of the first and second plate bodies are brought to overlap each other and are coupled together with the use of fasteners.

Preferably, the method of assembling a backlight module further includes, after step C), a step of:

E) disposing the optical film on the light guide plate.

### BRIEF DESCRIPTION OF THE DRAWINGS

Other features and advantages of the present invention will become apparent in the following detailed description of the preferred embodiments with reference to the accompanying drawings, of which;

FIG. 1 is an exploded perspective view illustrating a conventional liquid crystal display device;

FIG. 2 is an exploded perspective view illustrating a liquid crystal display device of a first preferred embodiment of the present invention;

FIG. 3 is an exploded perspective view illustrating a backlight module of the liquid crystal display device of FIG. 2;

FIG. 4 is a flowchart illustrating an assembly procedure of the backlight module of FIG. 3;

FIG. 5 are cross-sectional schematic views showing the assembly procedure of the backlight module of FIG. 3;

FIG. 6 are partly cross-sectional schematic views showing the assembly procedure of a modified backlight module having light-emitting diode modules as light sources;

FIG. 7 is a partly cross-sectional schematic view along the direction of first side wall structures and second side wall structures to illustrate the structure of the liquid crystal display device of FIG. 2;

FIG. 8 is a partly cross-sectional schematic view along the direction of a first side part structure to illustrate the structure of the liquid crystal display device of FIG. 2;

FIG. 9 is a partly cross-sectional schematic view along the direction of a second side part structure to illustrate the structure of the liquid crystal display device of FIG. 2;

FIG. 10 is a partly cross-sectional schematic view along the direction of the first side part structure to illustrate the structure of a first modification of a spacer unit;

FIG. 11 is a partly cross-sectional schematic view along the direction of the second side part structure to illustrate the structure of the first modification of the spacer unit;

FIG. 12 is a partly cross-sectional schematic view along the direction of the first and second side wall structures to illustrate the structures of a second modification and a third modification of the spacer unit;

FIG. 13 is a partly cross-sectional schematic view along the direction of the first side part structure to illustrate the structure of the second modification of the spacer unit;

FIG. 14 is a partly cross-sectional schematic view along the direction of the second side part structure to illustrate the structure of the second modification of the spacer unit;

FIG. 15 is a partly cross-sectional schematic view along the direction of the first side part structure to illustrate the structure of the third modification of the spacer unit;

FIG. 16 is a partly cross-sectional schematic view along the direction of the second side part structure to illustrate the structure of the third modification of the spacer unit;

FIG. 17 is a partly cross-sectional schematic view along the direction of the first and second side wall structures to illustrate the structure of a liquid crystal display device of a second embodiment of the present invention;

FIG. 18 is a flowchart illustrating an assembly procedure of a backlight module of the liquid crystal display device of FIG. 17;

FIG. 19 are cross-sectional schematic views showing the assembly procedure of the backlight module of FIG. 18;

FIG. 20 are partly cross-sectional schematic views showing the assembly procedure of a modified backlight module having light-emitting diode modules as light sources;

FIG. 21 is a cross-sectional schematic view showing a first groove of a first back plate and a second groove of a second back plate of another modified backlight module;

FIG. 22 is a cross-sectional schematic view showing a first protrusion of a first back plate and a second protrusion of a second back plate of yet another modified backlight module; and

FIG. 23 is a cross-sectional schematic view showing first and second protrusions on first and second back plates of still another modified backlight module.

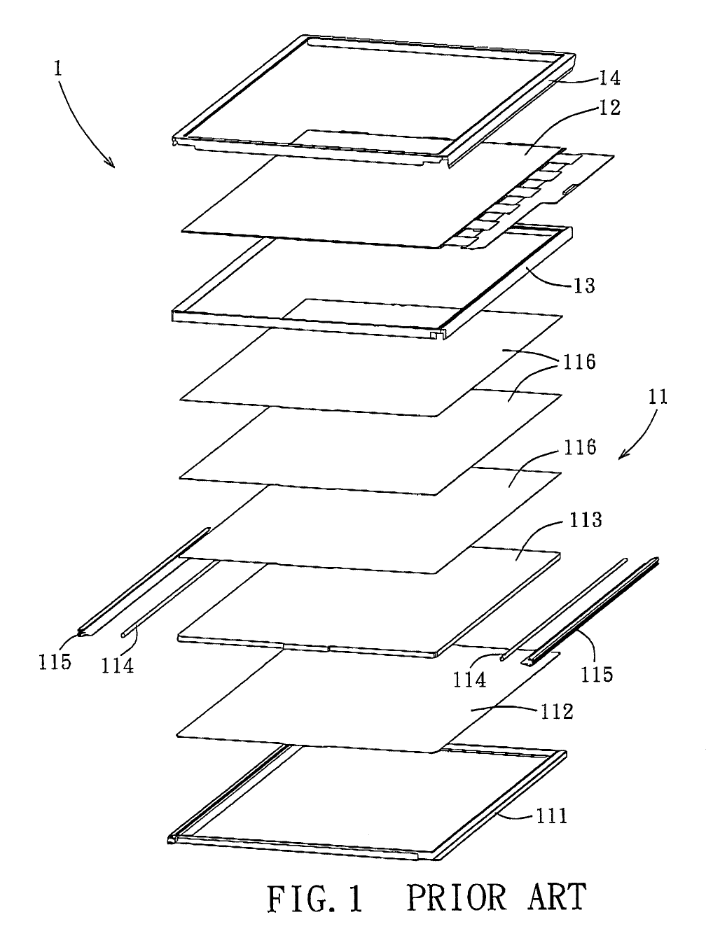

### DETAILED DESCRIPTION OF THE PREFERRED EMBODIMENTS

Before the present invention is described in greater detail with reference to the preferred embodiments, it should be noted that the same reference numerals are used to denote the same elements throughout the following description.

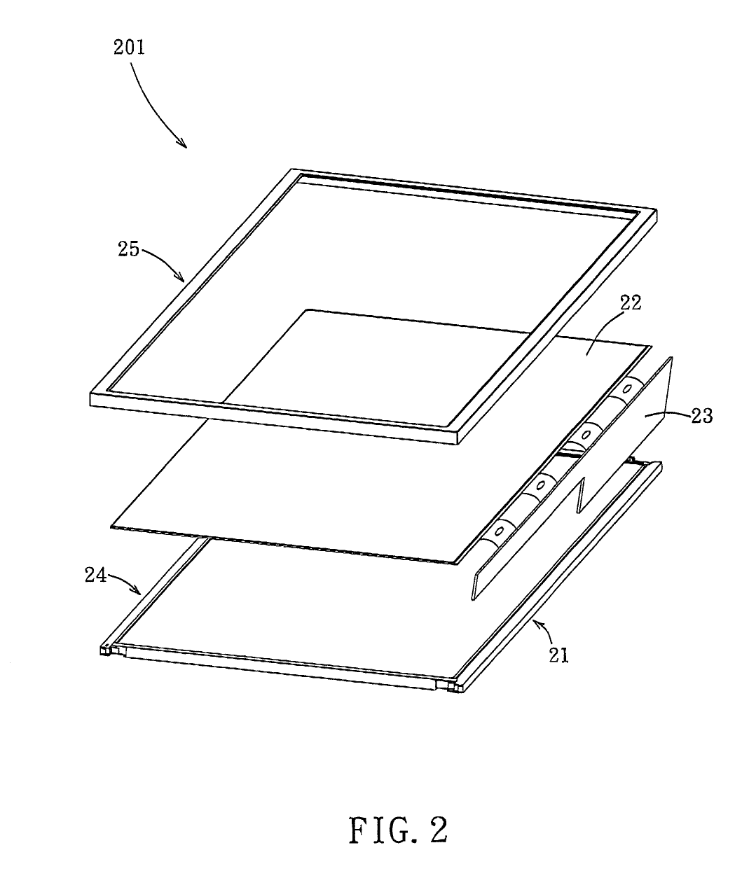

Referring to FIG. 2, in a first preferred embodiment of a liquid crystal display (LCD) device 20 according to the present invention, the LCD device 201 includes a backlight module 21, a liquid crystal panel 22, a circuit board 23, a spacer unit 24, and a bezel 25. The spacer unit 24 is disposed between the liquid crystal panel 22 and the backlight module 21 for separating the liquid crystal panel 22 from the backlight module 21 by a distance, and the liquid crystal panel 22 is fixed on the backlight module 21 by the bezel 25. The circuit board 23 is connected to the liquid crystal panel 22.

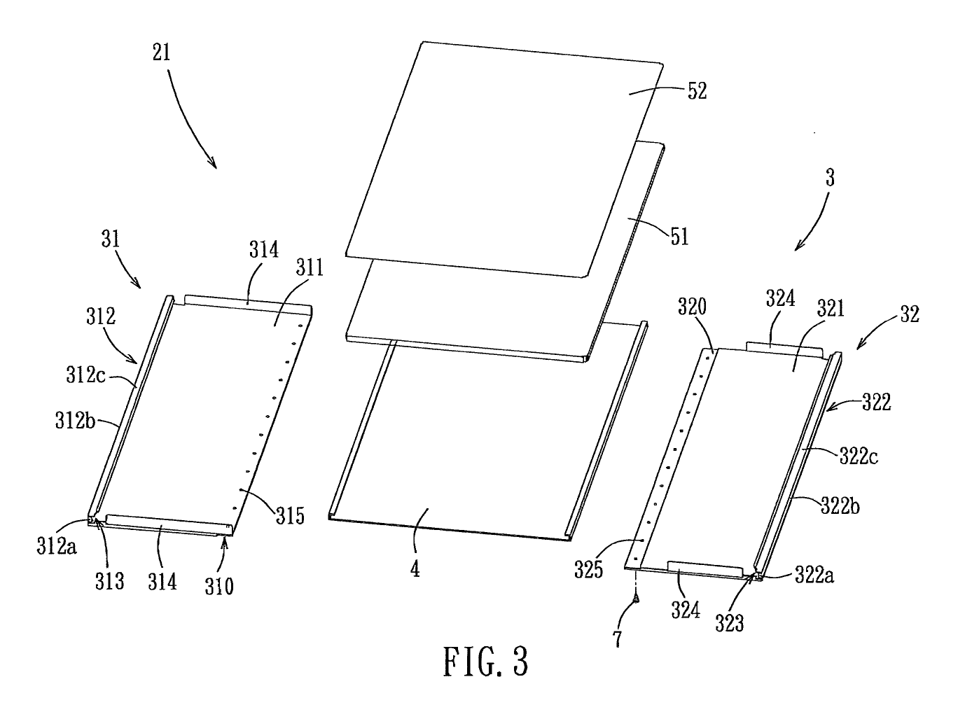

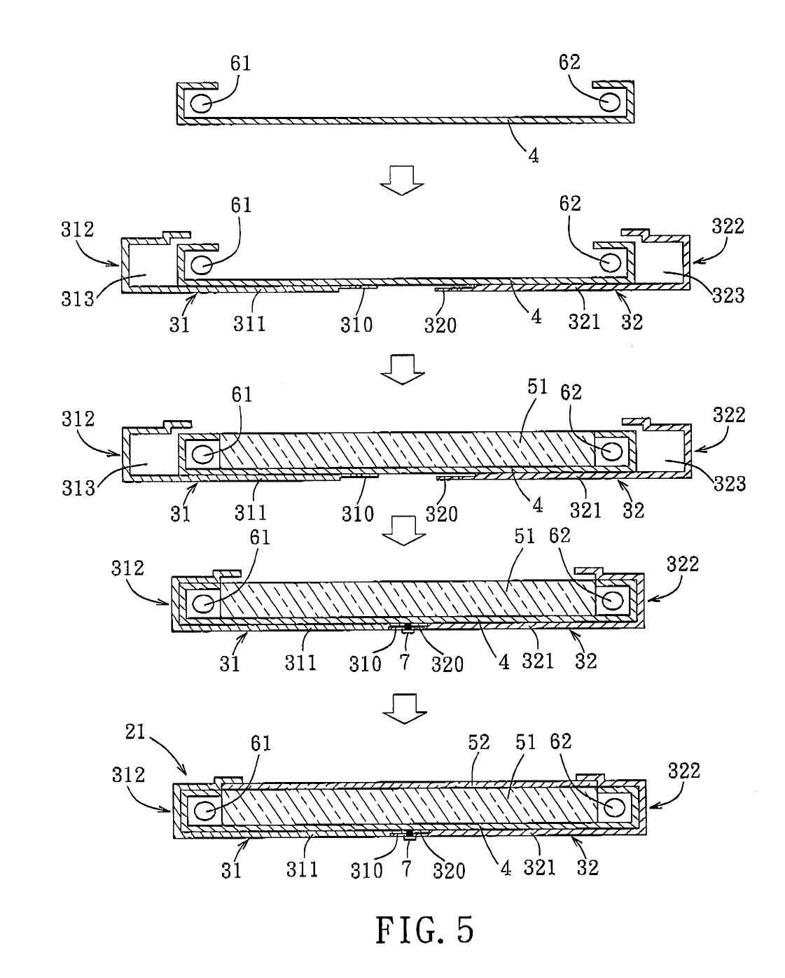

Referring to FIGS. 3 and 5, the backlight module 21 includes a back plate unit 3, a reflector unit 4, a light guide plate 51, an optical film 52, a first light source 61, and a second light source 62. The reflector unit 4 is disposed on the back plate unit 3, and the light guide plate 51 and the optical film 52 are stacked on the reflector unit 4 in sequence. The first light source 61 and the second light source 62 are disposed adjacent to opposite sides of the light guide plate 51, respectively, and are received in the back plate unit 3.

The back plate unit 3 includes a first back plate 31 and a second back plate 32. The first back plate 31 includes a rectangular first plate body 311. The first plate body 311 has opposite first and second edge parts, and a first side part structure 312 is connected to the first edge part of the first plate body 311. The second edge part of the first plate body 311 is formed with a first recessed surface 310 on a rear side of the first plate body 311, and a plurality of first fastener holes 315 are formed in the second edge part of the first plate body 311. The first plate body 311 further has opposite third and fourth edge parts that extend between the first and second edge parts of the first plate body 311, and each of a pair of first side wall structures 314 is connected to a respective one of the third and fourth edge parts of the first plate body 311. The first side part structure 312 includes a first surrounding wall 312b extending transversely from a front surface of the first plate body 311, a first end wall 312c extending from a distal end of the first surrounding wall 312b at an angle toward the second edge part of the first plate body 311 and spaced apart from the first plate body 311, and a pair of first side walls 312a, each extending from a respective one of two ends of the first surrounding wall 312b at an angle toward a respective one of the first side wall structures 314. The first surrounding wall 312b, the first end wall 312c and the first side walls 312a cooperate to define a first receiving space 313. In this embodiment, the first side part structure 312, the first side wall structures 319 and the first plate body 311 are formed integrally.

The second back plate 32 includes a rectangular second plate body 321. The second plate body 321 has opposite first and second edge parts, and a second side part structure 322 is connected to the first edge part of the second plate body 321. The second edge part of the second plate body 321 is formed with a second recessed surface 320 on a front side of the second plate body 321, and a plurality of second fastener holes 325 are formed in the second edge part of the second plate body 321. The second plate body 321 further has opposite third and fourth edge parts that extend between the first and second edge parts of the second plate body 321, and each of a pair of second side wall structures 324 is connected to a respective one of the third and fourth edge parts of the second plate body 321. The second side part structure 322 includes a second surrounding wall 322b extending transversely from a front surface of the second plate body 321, a second end wall 322c extending from a distal end of the second surrounding wall 322b at an angle toward the second edge part of the second plate body 321 and spaced apart from the second plate body 321, and a pair of second side walls 322a, each extending from a respective one of two ends of the second surrounding wall 322b at an angle toward a respective one of the second side wall structures 329. The second surrounding wall 322b, the second end wall 322c and the second side walls 322a cooperate to define a second receiving space 323. In this embodiment, the second side part structure 322, the second side wall structures 324 and the second plate body 321 are formed integrally.

The first plate body 311 and the second plate body 321 are interconnected with the second edge part of the first plate body 311 overlapping the second edge part of the second plate body 321 so as to form a receiving plane. The receiving plane, the first side part structure 312, the second side part structure 322, the first side wall structures 314, and the second side wall structures 324 cooperate to define an accommodating space.

The reflector unit 4 is disposed on the receiving plane formed by the first and second plate bodies 311, 321, and the reflector unit 4 has an end portion extending into the first receiving space 313 and an opposite end portion extending into the second receiving space 323. In this embodiment, the end portion and the opposite end portion of the reflector unit 4 are substantially C-shaped to match the first and second side part structures 312, 322. The reflector unit 4 has a light-reflecting function and can serve as a lampshade. Referring to FIG. 3, the reflector unit 4 may be a reflective plate or a reflective material coated on the inner wall faces of the first and second side part structures 312, 322.

The light guide plate 51 is disposed on the reflector unit 4 and between the first side part structure 312 and the second side part structure 322. The optical film 52 is disposed on the light guide plate 51. The optical film 52 can be a brightness enhancing film, a prism sheet, a diffuser sheet, etc. One or more optical films 52 may be disposed on the light guide plate 51. It is noted that the optical film 52 is optional and may be omitted in some embodiments of the invention.

The first light source 61 is received in the first receiving space 313 and is adjacent to an end portion of the light guide plate 51. The second light source 62 is received in the second receiving space 323 and is adjacent to an opposite end portion of the light guide plate 51. In this embodiment, the first and second light sources 61, 62 are cold cathode fluorescent lamps.

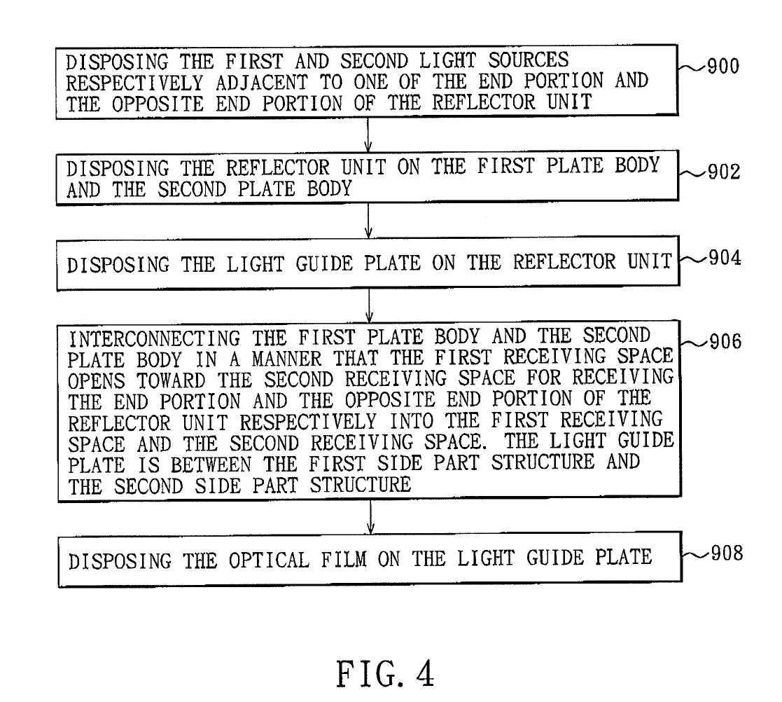

Referring to FIG. 4 and FIG. 5, a method of assembling the backlight module 21 of the first preferred embodiment includes the steps of:

900) disposing the first and second light sources 61, 62 respectively adjacent to one of the end portion and the opposite end portion of the reflector unit 4. The end portions of the reflector unit 4 are bent to be substantially C-shaped for receiving the first and second light sources 61, 62.

902) disposing the reflector unit 4 on the first plate body 311 and the second plate body 321. The first back plate 31 and the second back plate 32 are arranged in a manner that the first receiving space 313 opens toward the second receiving space 323 with the second edge parts of the first and second plate bodies 31, 32 spaced apart from each other.

904) disposing the light guide plate 51 on the reflector unit 4.

906) interconnecting the first plate body 311 and the second plate body 321 in a manner that the first receiving space 313 opens toward the second receiving space 323 for receiving the end portion and the opposite end portion of the reflector unit 4 respectively into the first receiving space 313 and the second receiving space 323. The light guide plate 51 is between the first side part structure 312 and the second side part structure 322 at this time.

More specifically, the first recessed surface 310 of the first plate body 311 overlaps the second recessed surface 320 of the second plate body 321, i.e., the second edge part of the first plate body 311 overlaps the second edge part of the second plate body 321. Screw fasteners 7 pass through the first fastener holes 315 and the second fastener holes 325 so as to fasten together the first back plate 31 and the second back plate 32. The fastening mechanism between the first and second back plates 31, 32 is not limited in this preferred embodiment, and a locking device or other connecting structures may be employed instead of the first recessed surface 310 and the second recessed surface 320.

Moreover, the first and second light sources 61, 62 have been disposed adjacent to a respective one of the end portion and the opposite end portion of the reflector unit 4. Thus, the first, and second light sources 61, 62 are received in the respective one of the first and second receiving spaces 313, 323 when the first back plate 31 is connected to the second back plate 32.

908) disposing the optical film 52 on the light guide plate 51. Because the optical film 52 is flexible, it can be flexed for fitting in the accommodating space.

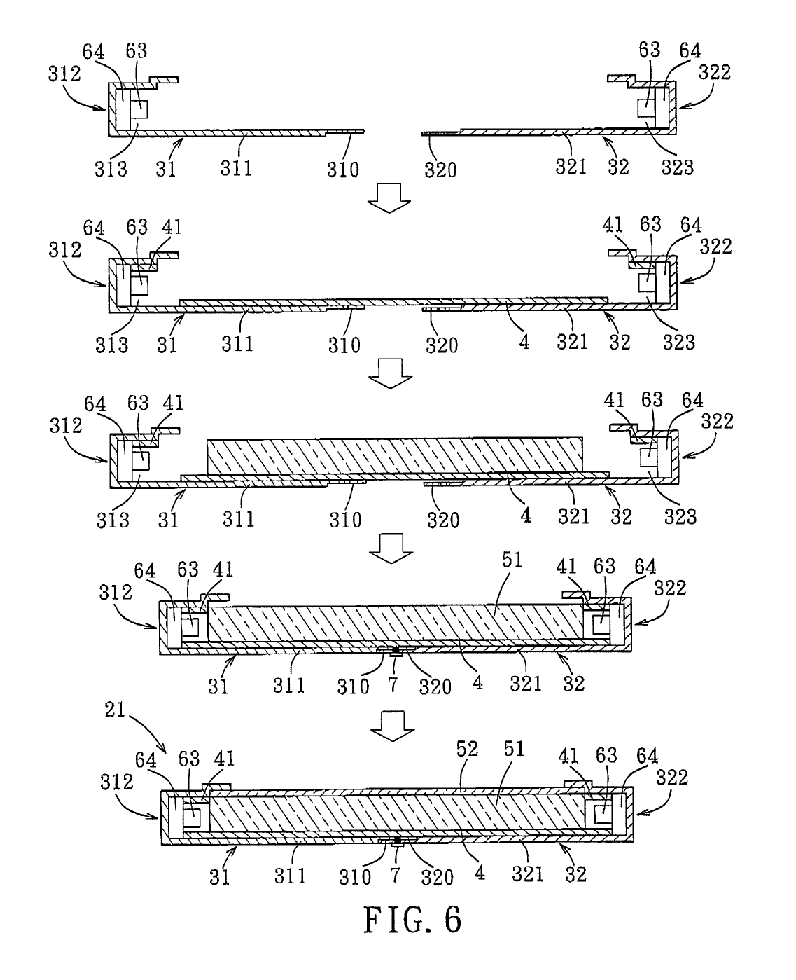

Furthermore, referring to FIG. 6, the first light source 61 and the second light source 62 may be light-emitting diode (LED) modules in other embodiments of the invention. Each of the LED modules has a LED component 63 and a circuit base 64. When LED modules are used, a step 900′) may be used instead of step 900) in the method of assembling the backlight module 21, with the other steps unchanged.

900′) disposing the first light source 61 and the second light source 62 respectively in the first receiving space 313 and the second receiving space 323. More specifically, each circuit base 64 is mounted on a respective one of the inner wall faces of the first surrounding wall 312b of the first side part structure 312 and the second surrounding wall 322b of the second side part structure 322 by means of heat conductive glue. Thus, the heat generated by the LED components 63 may be dissipated effectively through the first back plate 31 and the second back plate 32. Because the circuit bases 64 are mounted on the inner wall faces of the first and second surrounding walls 312b, 322b, the reflector unit 4 has a planar shape in FIG. 6. Preferably, in step 902), a pair of reflector components 41 with small dimensions are mounted on the inner wall faces of the first end wall 312c and the second end wall 322c for enhancing the reflecting effect.

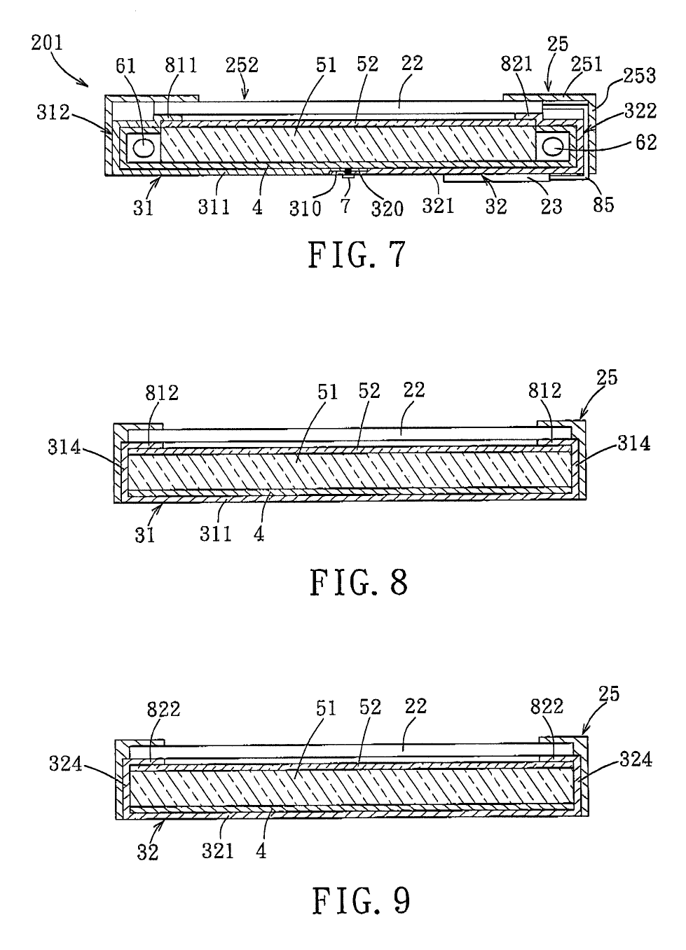

Referring to FIG. 7, FIG. 8 and FIG. 9, the spacer unit 24 is disposed on the backlight module 21. The spacer unit 24 includes a first support flange 811 extending from the first side part structure 312, a pair of first liners 812 each extending from a respective one of the first side wall structures 314, a second support flange 821 extending from the second side part structure 322, and a pair of second liners 822 each extending from a respective one of the second side wall structures 324. The first support flange 811 and the first liners 812 are formed integrally with the first back plate 31. The second support flange 821 and the second liners 822 are formed integrally with the second back plate 32.

The liquid crystal panel 22 is disposed on the first support flange 811, the second support flange 821, the first liners 812 and the second liners 822, and is thus separated from the backlight module 21. In this way, the liquid crystal panel 22 will not be scratched or damaged due to contact with the backlight module 21.

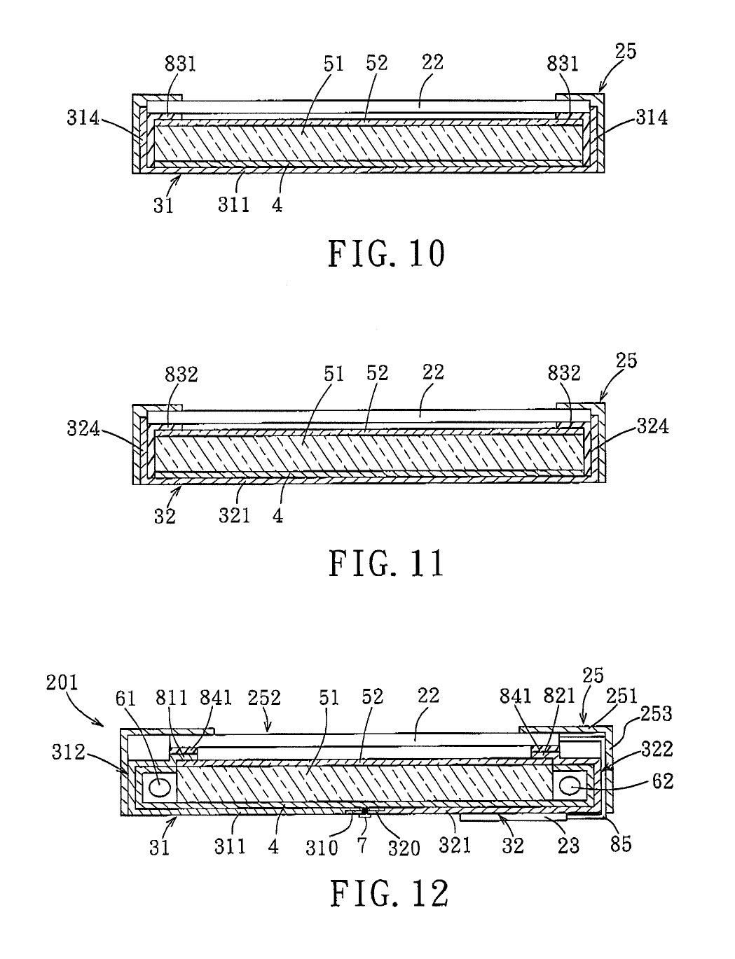

In this embodiment, the spacer unit 24 may have other configurations for spacing the liquid crystal panel 22 apart from the backlight module 21. Referring to FIG. 7, FIG. 10 and FIG. 11 according to a first modification of the spacer unit 24, each of a pair of first liners 831 is disposed between the light guide plate 51 and a respective one of the first side wall structures 314, and each of a pair of second liners 832 is disposed between the light guide plate 51 and a respective one of the second side wall structures 324. The spacer unit 24 further includes a first support flange 811 extending from the first side part structure 312, and a second support flange 821 extending from the second side part structure 322. The structures of the first and second support flanges 811, 812 are the same as those mentioned above. Each of the first and second liners 831, 832 has a portions extending over the optical film 52. In this way, the liquid crystal panel 22 is disposed on the extending portion of the first and second liners 831, 832, the first support flange 811 and the second support flange 821.

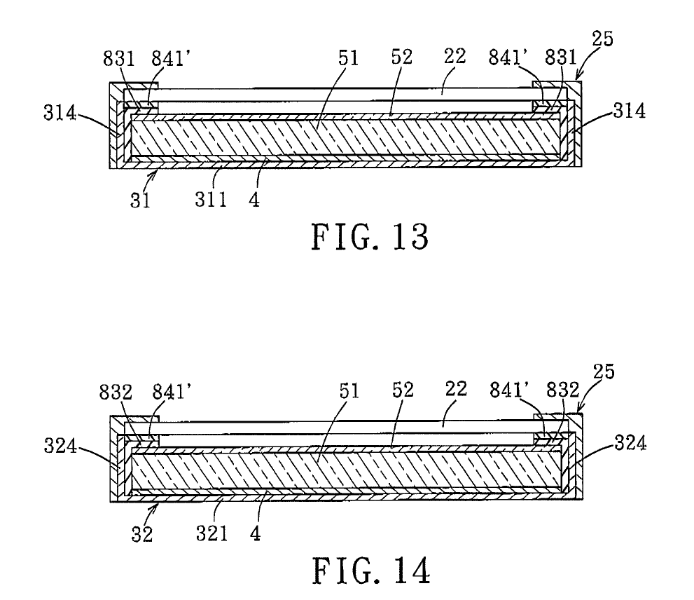

Referring to FIG. 12, FIG. 13 and FIG. 14, according to a second modification of the spacer unit 24, each of a pair of first spacer strips 841 is disposed on a respective one of the first support flange 811 and the second support flange 821, each of four second spacer strips 841′ is disposed on the extending portion of a respective one of the first and second liners 831, 832. In this way, the liquid crystal panel 22 is disposed on the first spacer strips 841 and the second spacer strips 841′, and is spaced farther apart from the backlight module 21 compared to the first modification of the spacer unit 24.

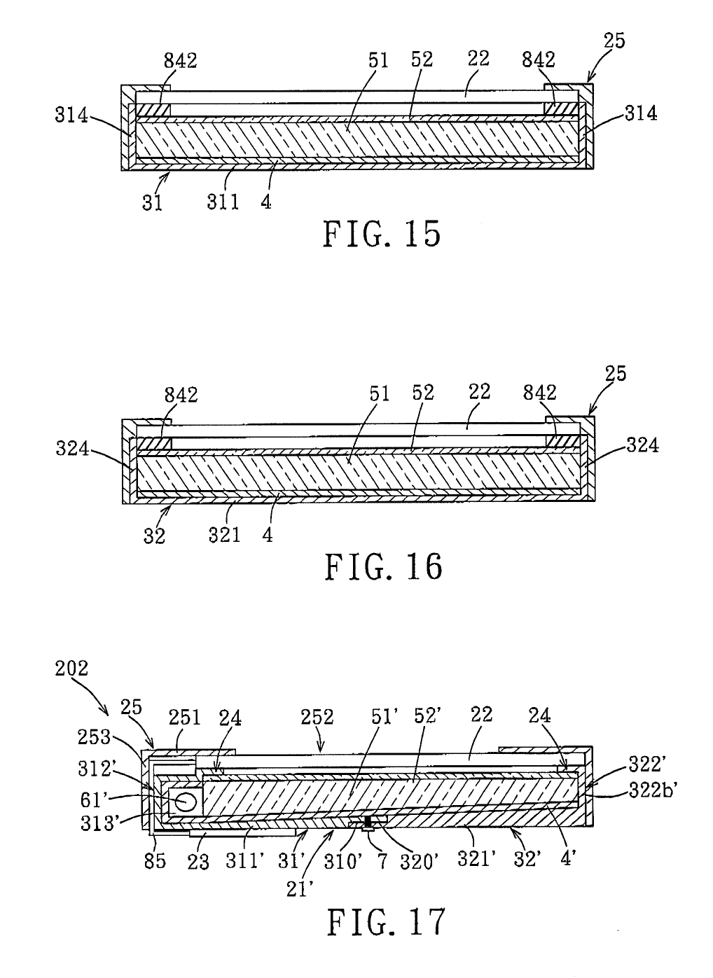

Referring to FIG. 12, FIG. 15 and FIG. 16, according to a third modification of the spacer unit 24, a first support flange 811 extends from the first side part structure 312, a second support flange 821 extending from the second side part structure 322, each of a pair of first spacer strips 841 is disposed on a respective one of the first and second support flanges 811, 821, and each of four second spacer strips 842 is disposed on the optical film 52. The second spacer strips 892 are used to replace the first and second liners 831, 832 and the second spacer strips 841′ in the second modification of the spacer unit 24. In this way, the liquid crystal panel 22 is disposed on the first spacer strips 841 and the second spacer strips 842.

The structure of the spacer unit 24 described above are non-limiting examples of the present invention. Those skilled in the art may readily appreciate other suitable forms of the spacer unit 24 for spacing the liquid crystal panel 22 apart from the backlight module 21.

Referring again to FIG. 7, the circuit board 23 is connected to the liquid crystal panel 22 through a flexible cable 85. The circuit board 23 is disposed on the rear side of the second plate body 321 and adjacent to the second side part structure 322. The flexible cable 85 is arranged between the bezel 25 and the second side part structure 322 of the second back plate 32. However, depending on the structure of the liquid crystal panel 22, the circuit board 32 may be disposed on the rear side of the first plate body 311 and adjacent to the first side part structure 312, and the flexible cable 85 may be arranged between the bezel 25 and the first side part structure 312 of the first back plate 31.

The bezel 25 includes a surrounding wall 253 and a press wall 251 connected to a periphery of the surrounding wall 253 and defining an opening 252 for exposing the liquid crystal panel 22. The bezel 25 couples the liquid crystal panel 22 to the backlight module 21 in a manner that the surrounding wall 253 surrounds the back plate unit 3, and the press wall 251 presses against the liquid crystal panel 22 so that the entire structure of the LCD device 201 is made stronger.

Referring to FIG. 17, a second preferred embodiment of the LCD device 202 of the present invention includes a backlight module 21′, a liquid crystal panel 22, a circuit board 23, a spacer unit 24, and a bezel 25. The main difference between the second embodiment and the first embodiment resides in the backlight module 21′. The backlight module 21′ of the LCD device 202 includes only one light source 61′, and the second side part structure 322′ of the second back plate 32′ only includes a second surrounding wall 322b′. Only one end portion of a reflector unit 4′ is substantially C-shaped. Furthermore, in order to match the single light source design, the structures of the reflector unit 4′, the light guide plate 51′, the first back plate 31′ and the second back plate 32′ are all altered as compared with the first preferred embodiment. Since the alterations may be readily appreciated by those skilled in the art from the drawing, further details of the same are omitted herein for the sake of brevity. The structures and functions of other parts of the LCD device 202 are the same as those of the first preferred embodiment, and a description thereof will not be repeated herein.

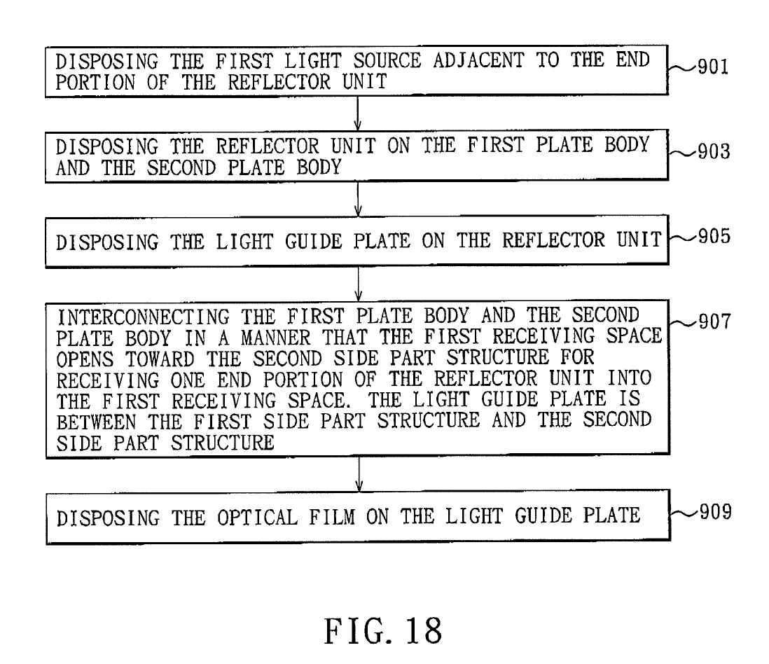

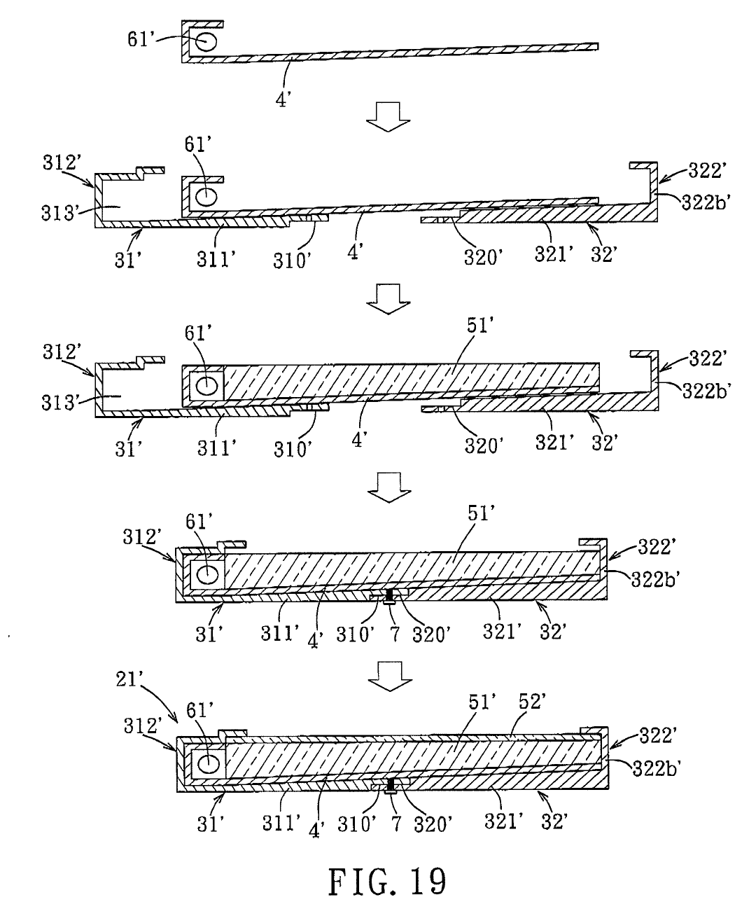

Referring to FIG. 18 and FIG. 19, a method of assembling the backlight module 21′ of the second preferred embodiment includes the steps of:

901) disposing the first light source 61′ adjacent to the end portion of the reflector unit 4′.

903) disposing the reflector unit 4′ on the first plate body 311′ and the second plate body 312′ similar to step 902) of the first preferred embodiment.

905) disposing the light guide plate 51′ on the reflector unit 4′.

907) interconnecting the first plate body 311′ and the second plate body 321′ in a manner that the first receiving space 313′ opens toward the second side part structure 322′ for receiving the end portion of the reflector unit 4′ into the first receiving space 313′. The light guide plate 51′ is between the first side part structure 312′ and the second side part structure 322′ at this time. The manner of interconnecting the first back plate 31′ and the second back plate 32′ is the same as that mentioned in step 906) of the method of the first preferred embodiment.

909) disposing the optical film 52′ on the light guide plate 51′.

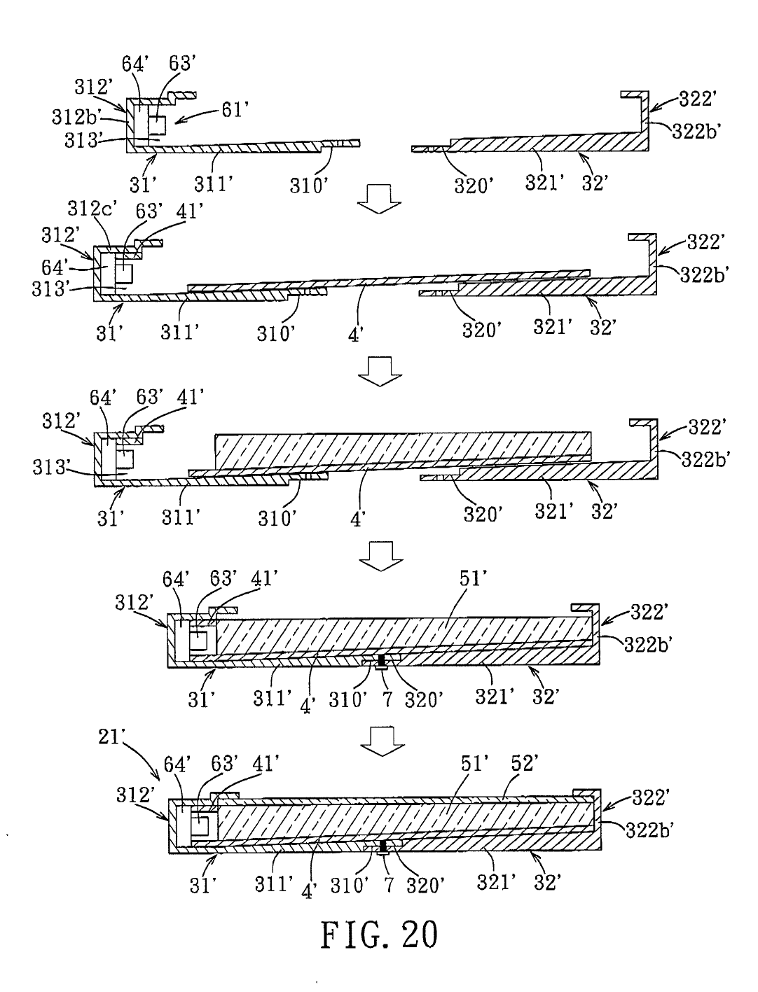

Moreover, referring to FIG. 20, the first light source 61′ may be a LED module. The LED module has a LED component 63′ and a circuit base 64′. When the LED module is used, a step 901′) may be used instead of step 901) in the method of assembling the backlight module 21′, with the other steps unchanged.

901′) disposing the first light source 61′ in the first receiving space 313′. More specifically, the circuit base 64′ is mounted on the inner wall face of the first surrounding wall 312b′ of the first side part structure 312′ by means of heat conductive glue. Thus, the heat generated by the LED component 63′ may be dissipated effectively through the first back plate 31′. Because the circuit base 64′ is mounted on the inner wall face of the first surrounding wall 312b′, the reflector unit 4′ has a planar shape in FIG. 20. Preferably, in step 903), a reflector component 41′ with small dimensions is mounted on the inner wall face of the first end wall 312c′ for enhancing the reflecting effect.

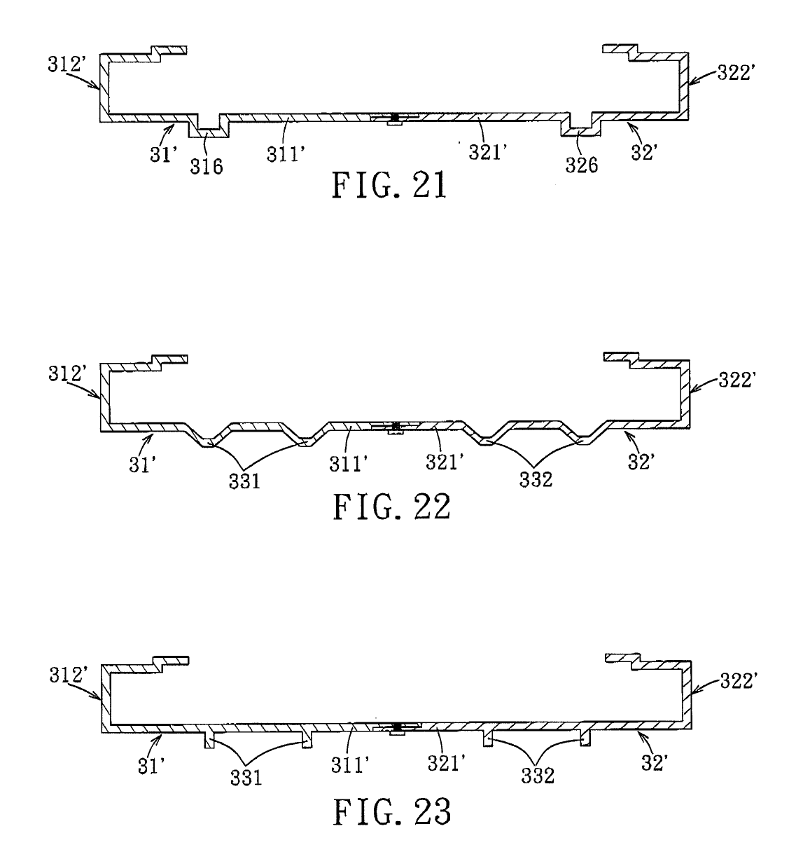

Additionally, referring to FIG. 21, the first plate body 311′ of the first back plate 31′ of the backlight module of the LCD device 202 of the present invention

May be configured to have one side that confronts the light guide plate 51′ (see FIG. 17) and that is formed with a first groove 316 adjacent to the first side part structure 312′. The second plate body 321′ of the second back plate 32′ of the backlight module of the LCD device 202 of the present invention may be configured to have one side that confronts the light guide plate 51′ (see FIG. 17) and that is formed with a second groove 326 adjacent to the second side part structure 322′. When there are wires or cables (not shown) arranged in the backlight module 21′, the wires or the cables may be received in the first groove 316 and the second groove 326. Thus, containers or other receiving objects attached to the backlight module 21′ may be omitted to save cost and space, and the wires or the cables may be prevented from being undesirably pulled or caught. The back plate unit 3 of the LCD device 201 of the first preferred embodiment may be provided with the same design.

Furthermore, referring to FIG. 22 and FIG. 23, the first plate body 311′ of the first back plate 31′ of the backlight module of the LCD device 202 of the present invention may be configured to have one side that is opposite to the light guide plate 51′ (see FIG. 17) and that is formed with a plurality of first protrusions 331 adjacent to the first side part structure 312′, and the second plate body 321′ of the second back plate 32′ of the LCD device 202 of the present invention has one side that is opposite to said light guide plate 51′ and that is formed with a plurality of second protrusions 332 adjacent to the second side part structure 322′. The circuit board 23 (see FIG. 17) and a power source (not shown) may be attached to the first plate body 311′ and the second plate body 321′ at the first protrusions 331 and the second protrusions 332, such that additional supports for fixing the circuit board 23 and the power source may be omitted, and the cost of the LCD device 202 may be further reduced. The first and second protrusions 331, 332 may be formed through molding or riveting techniques. The back plate unit 3 of the LCD device 201 of the first preferred embodiment may be provided with the same design.

In summary, lampshades may be omitted and costs may be reduced by virtue of the design of the back plate units 3, 3′ and the structures of the first side part structures 312, 312′, the second side part structures 322, 322′ and the reflector units 4, 4′ of the backlight modules 21, 21′ of the LCD devices 201, 202 of the present invention. In assembling the backlight modules 21, 21′, the reflector units 4, 4′, the light guide plates 51, 51′, the first light sources 61, 61′, and the second light source 62 are disposed and assembled more conveniently since the first back plate 31, 31′ and the second back plate 32, 32′ are initially arranged apart from each other. Thus, time and manpower for assembling the backlight modules 21, 21′ can be saved and costs maybe reduced. Besides, by providing the first grooves 316, the second grooves 326, the first protrusions 331 and the second protrusions 332, costs may be further reduced.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A backlight module comprising:
a first light source;
a back plate unit including
a first back plate having a first plate body with opposite first and second edge parts, and a first side part structure connected to said first edge part of said first plate body, said first side part structure defining a first receiving space for receiving said first light source, said first receiving space opening toward said second edge part of said first plate body, and
a second back plate having a second plate body with opposite first and second edge parts, and a second side part structure connected to said first edge part of said second plate body,
said second back plate being connected to said first back plate in a manner that said first and second side part structures are opposite to each other;
a reflector unit disposed on said first and second plate bodies, said reflector unit having a portion extending into said first receiving space; and
a light guide plate disposed on said reflector unit and disposed between said first and second side part structures.

2. The backlight module as claimed in claim 1, further comprising a second light source, said second side part structure defining a second receiving space for receiving said second light source, said second receiving space opening toward said second edge part of said second plate body, said reflector unit having another portion extending into said second receiving space.

3. The backlight module as claimed in claim 2, wherein said portion of said reflector unit that extends into said first receiving space is disposed between said first side part structure and said first light source, and said another portion of said reflector unit that extends into said second receiving space is disposed between said second side part structure and said second light source.

4. The backlight module as claimed in claim 3, wherein:
said first plate body further has opposite third and fourth edge parts that extend between said first and second edge parts of said first plate body;
said first back plate further having a pair of first side wall structures, each connected to a respective one of said third and fourth edge parts of said first plate body;
said second plate body further having opposite third and fourth edge parts that extend between said first and second edge parts of said second plate body;
said second back plate further having a pair of second side wall structures, each connected to a respective one of said third and fourth edge parts of said second plate body.

5. The backlight module as claimed in claim 4, wherein:
said first plate body has one side that confronts said light guide plate and that is formed with a first groove adjacent to said first side part structure; and
said second plate body has one side that confronts said light guide plate and that is formed with a second groove adjacent to said second side part structure.

6. The backlight module as claimed in claim 4, wherein:
said first plate body has one side that is opposite to said light guide plate and that is formed with a plurality of first protrusions adjacent to said first side part structure; and
said second plate body has one side that is opposite to said light guide plate and that is formed with a plurality of second protrusions adjacent to said second side part structure.

7. The backlight module as claimed in claim 1, wherein said second edge part of said second plate body is formed with a recessed surface, said second edge part of said first plate body overlapping said recessed surface.

8. A liquid crystal display device comprising:
a backlight module including
a first light source,
a back plate unit including
a first back plate having a first plate body with opposite first and second edge parts, and a first side part structure connected to said first edge part of said first plate body, said first side part structure defining a first receiving space for receiving said first light source, said first receiving space opening toward said second edge part of said first plate body, and
a second back plate having a second plate body with opposite first and second edge parts, and a second side part structure connected to said first edge part of said second plate body,
said second back plate being connected to said first back plate in a manner that said first and second side part structures are opposite to each other,
a reflector unit disposed on said first and second plate bodies, said reflector unit having an end portion extending into said first receiving space, and
a light guide plate disposed on said reflector unit and disposed between said first and second side part structures; and
a liquid crystal panel coupled to said backlight module.

9. The liquid crystal display device as claimed in claim 8, further comprising a bezel for coupling said liquid crystal panel to said backlight module, said bezel including
a surrounding wall disposed to surround said back plate unit, and
a press wall connected to a periphery of said surrounding wall and disposed to press against said liquid crystal panel.

10. The liquid crystal display device as claimed in claim 9, wherein said backlight module further includes a second light source, said second side part structure defining a second receiving space for receiving said second light source, said second receiving space opening toward said second edge part of said second plate body, said reflector unit having another portion extending into said second receiving space.

11. The liquid crystal display device as claimed in claim 10, wherein said portion of said reflector unit that extends into said first receiving space is disposed between said first side part structure and said first light source, and said another portion of said reflector unit that extends into said second receiving space is disposed between said second side part structure and said second light source.

12. The liquid crystal display device as claimed in claim 11, wherein:
said first plate body further has opposite third and fourth edge parts that extend between said first and second edge parts of said first plate body;
said first back plate further having a pair of first side wall structures, each connected to a respective one of said third and fourth edge parts of said first plate body;
said second plate body further having opposite third and fourth edge parts that extend between said first and second edge parts of said second plate body;
said second back plate further having a pair of second side wall structures, each connected to a respective one of said third and fourth edge parts of said second plate body.

13. The liquid crystal display device as claimed in claim 12, further comprising a spacer unit disposed between said backlight module and said liquid crystal panel, said spacer unit including
a first support flange extending from said first side part structure and disposed between said light guide plate and said liquid crystal panel,
a second support flange extending from said second side part structure and disposed between said light guide plate and said liquid crystal panel,
a pair of first liners, each disposed between said light guide plate and a respective one of said first side wall structures and extending between said light guide plate and said liquid crystal panel, and
a pair of second liners, each disposed between said light guide plate and a respective one of said second side wall structures and extending between said light guide plate and said liquid crystal panel.

14. The liquid crystal display device as claimed in claim 12, further comprising a spacer unit disposed between said backlight module and said liquid crystal panel, said spacer unit including
a first support flange extending from said first side part structure and disposed between said light guide plate and said liquid crystal panel,
a second support flange extending from said second side part structure and disposed between said light guide plate and said liquid crystal panel, and
a pair of spacer strips, each disposed between said light crystal panel and a respective one of said first and second support flanges.

15. A method of assembling a backlight module according to claim 2, comprising the steps of:
A) disposing said reflector unit on said first plate body and said second plate body;
B) disposing said light guide plate on said reflector unit; and
C) interconnecting said first plate body and said second plate body in a manner that said first receiving space and said second receiving space open toward each other, that said portions of said reflector unit respectively extend into said first and second receiving spaces, and that said light guide plate is disposed between said first and second side part structures.

16. The method as claimed in claim 15, further comprising, before step A), the step of:
D) disposing each of said first and second light sources at a respective one of said portions of said reflector unit such that each of said first and second light sources is disposed in a respective one of said first and second receiving spaces when said first and second plate bodies are interconnected in step C);
wherein each of said first and second light sources includes a lamp tube.

17. The method as claimed in claim 16, wherein:
in step A), said reflector unit is disposed on said first plate body and said second plate body, with said second edge parts of said first and second plate bodies spaced apart from each other; and
in step C), said second edge parts of said first and second plate bodies are brought to overlap each other and are coupled together with the use of fasteners.

18. A method of assembling a backlight module according to claim 1, comprising the steps of:
A) disposing said reflector unit on said first plate body and said second plate body;
B) disposing said light guide plate on said reflector unit; and
C) interconnecting said first plate body and said second plate body in a manner that said first receiving space opens toward said second side part structure, that said portion of said reflector unit extends into said first receiving space, and that said light guide plate is disposed between said first and second side part structures.

19. The method as claimed in claim 18, further comprising, before step A), the step of:
D) disposing said first light source at said portion of said reflector unit such that said first light source is disposed in said first receiving space when said first and second plate bodies are interconnected in step C);
wherein said first light source includes a lamp tube.

20. The method as claimed in claim 19, wherein:
in step A), said reflector unit is disposed on said first plate body and said second plate body, with said second edge parts of said first and second plate bodies spaced apart from each other; and
in step C), said second edge parts of said first and second plate bodies are brought to overlap each other and are coupled together with the use of fasteners.
